(19) United States
(12) Patent Application Publication
(10) Pub. No.: US 2003/0081382 A1
(43) Pub. Date: May 1, 2003

(54) Thermal module

(76) Inventor: Ching Huan Lin, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/027,198

(22) Filed: Dec. 20, 2001

(30) Foreign Application Priority Data
Oct. 31, 2001 (TW) 90218613

(51) Int. Cl. H05K 7/20

(52) U.S. Cl. 361/697; 361/700; 165/104.33

(57) ABSTRACT

A thermal module (10) includes a housing (12). The housing includes a contact portion (20), a receiving portion (22) and a fixing portion (24). A fan (18) fixed to the fixing portion of the housing generates airflow toward the receiving portion. A heat sink (14) is received in the receiving portion of the housing. The heat sink has a plurality of fins (36) defining a plurality of slots (38) therebetween, and an end surface (32). A first angle (θ) is defined between the end surface and any of the fins. A second angle is defined between the end surface and a direction of a substantial proportion of the airflow. The first angle is substantially equal to the second angle. Thus the slots are substantially aligned with the direction of the airflow. A heat pipe (16) is attached in the contact portion of the housing and the heat sink.

### BACKGROUND OF THE INVENTION

1. Field of the Invention

The present invention relates to thermal modules, and particularly to a thermal module having a heat sink, a heat pipe and a fan.

2. Related Art

An electrical system such as a computer system often has components that generate unwanted heat. Excessive heat can adversely affect operation of the computer system, and cause the system to become unstable. Therefore, a thermal module is widely used to remove heat from a heat generating component of a computer. Developments in computer chip technology have given computers central processing units (CPUs) with more functions and faster processing speeds. Accordingly, modern CPUs generate copious amounts of heat. At the same time, modern computers and their components are continually being miniaturized. Thus, thermal modules having very high heat dissipation efficiency are becoming increasingly important.

A conventional thermal module includes a housing, a heat sink received in the housing, a heat pipe, and a fan generating air flow to the heat sink. The housing has a contact portion for thermal contact with a heat generating component such as a CPU. The heat pipe has a first section which is attached in the contact portion for conducting heat from the heat generating component, and a second section which is received in the heat sink for dissipation of heat via the heat sink. The heat sink has a plurality of fins defining a plurality of slots therebetween, thereby providing a large heat dissipation surface. The fan generates airflow passing through the slots, thereby facilitating heat dissipation.

However, in a conventional thermal module, the direction of air flow generated from the fan is incompatible with the alignment of the fins of the heat sink. The airflow is unduly retarded by the fins, which reduces the heat dissipation efficiency of the module.

### SUMMARY OF THE INVENTION

Accordingly, an object of the present invention is to provide a thermal module having a heat sink with maximized heat dissipation efficiency.

To achieve the above-mentioned object, a thermal module comprises a housing. The housing comprises a contact portion, a receiving portion, and a fixing portion. A fan fixed to the fixing portion of the housing generates airflow toward the receiving portion. A heat sink is received in the receiving portion of the housing. The heat sink has a plurality of fins defining a plurality of slots therebetween, and an end surface. A first angle is defined between the end surface and any of the fins. A second angle is defined between the end surface and a direction of a substantial proportion of the airflow. The first angle is substantially equal to the second angle. Thus the slots are substantially aligned with the direction of the airflow generated from the fan. A heat pipe is attached in the contact portion of the housing and the heat sink.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded view of a thermal module in accordance with the present invention;

FIG. 2 is a perspective view of a heat sink of the thermal module of FIG. 1;

FIG. 3 is a cut-away view of the heat sink of FIG. 2, taken along line III-III of FIG. 2; and

FIG. 4 is an assembled view of FIG. 1.

### DETAILED DESCRIPTION OF THE PREFERRED EMBODIMENT

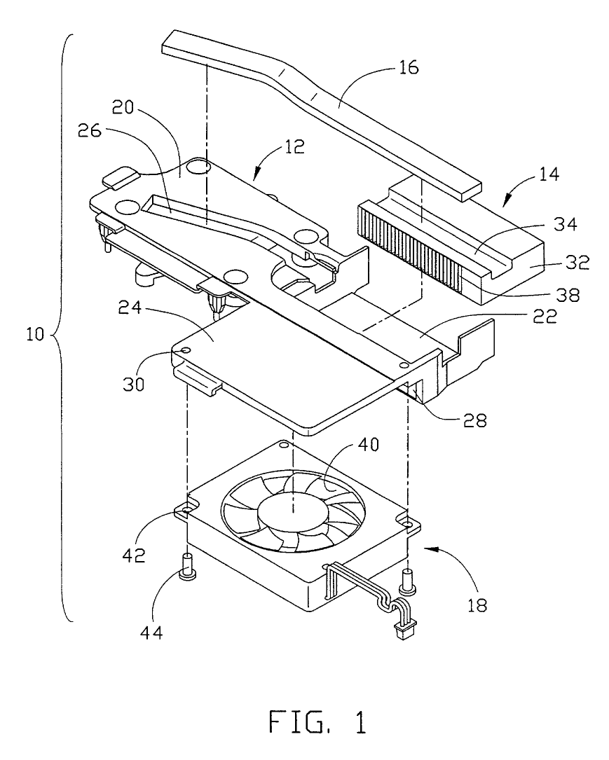

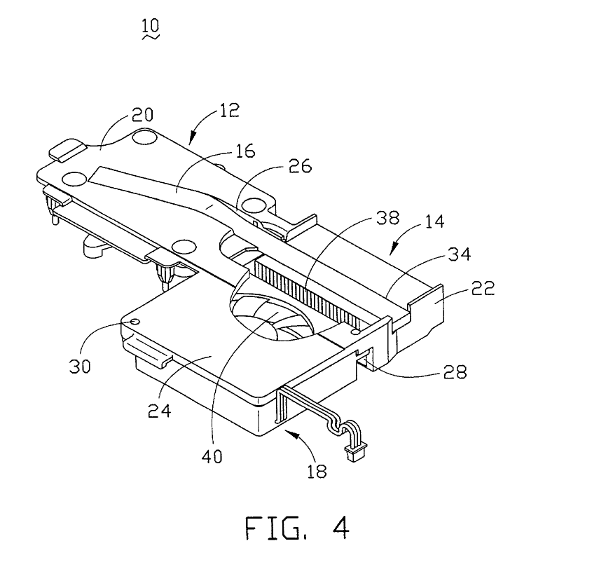

Referring to FIG. 1, a thermal module 10 in accordance with the present invention includes a housing 12, a heat sink 14, a heat pipe 16 and a fan 18. The housing 12 includes a contact portion 20 for thermal contact with a heat generating component such as a central processing unit (not shown), a receiving portion 22 extending from the contact portion 20, and a fixing portion 24 extending from the receiving portion 22. A first recess 26 is defined in a top face of the contact portion 20, for receiving a section of the heat pipe 16 (also see FIG. 4). An opening 28 is defined in a vertical face of the receiving portion 22 proximate the fixing portion 24. A pair of screw holes 30 is respectively defined in diagonally opposite corners of the fixing portion 24.

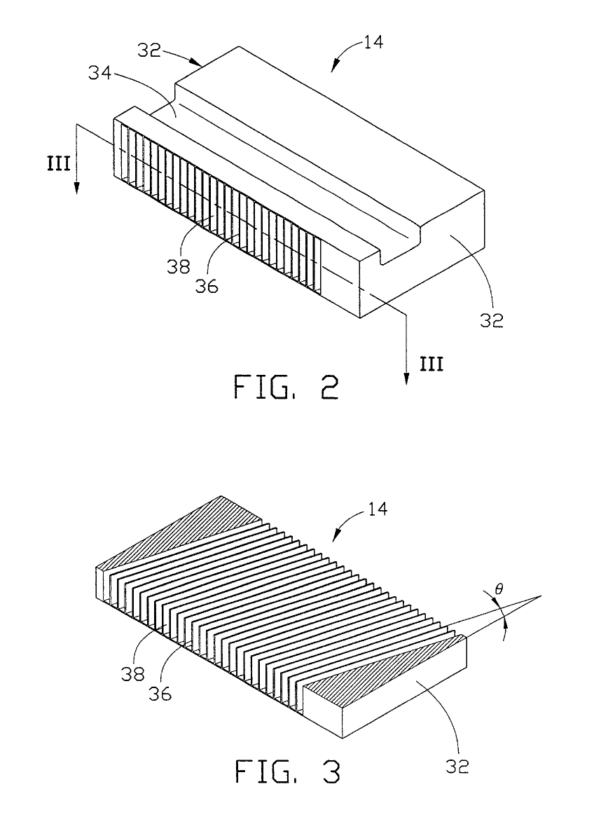

Referring to FIGS. 2 and 3, the heat sink 14 is substantially rectangular and has a pair of parallel end surfaces 32. A second recess 34 is defined in a top face of the heat sink 14 between the end surfaces 32, for receiving another section of the heat pipe 16 (also see FIG. 4). A plurality of parallel slots 38 is defined in the heat sink 14 beneath the second recess 34. A plurality of parallel fins 36 is thus formed in the heat sink 14 beneath the second recess 34, each fin 36 separating adjacent slots 38. An angle θ is defined between either end surface 32 and any of the fins 36. Thus, the angle θ is also defined between either end surface 32 and any of the slots 36.

Referring to FIG. 1, the fan 18 defines an exhaust vent 40 in one side wall thereof. Four through holes 42 are respectively defined in four corners of the fan 18. Two bolts 44 are for securing the fan 18 to the fixing portion 24 of the housing 12.

Referring to FIGS. 1 and 4, in assembly, the heat sink 14 is received in the receiving portion 22 of the housing 12. The heat pipe 16 is received in the first recess 26 of the contact portion 20 and in the second recess 34 of the heat sink 14. The fan 18 is fixed to the fixing portion 24 of the housing 12. The bolts 44 are extending through two of the through holes 42 of the fan 18 to threadedly engage in the screw holes 30 of the fixing portion 24. The vent 40 of the fan 18 is aligned with the opening 28 of the receiving portion 22 and the slots 38 of the heat sink 14. An angle θ′ (not shown) is defined between a direction of a substantial proportion of airflow generated from the fan 18 and flowing to the slots 38 and either end surface 32 of the heat sink 14. The angle θ′ is substantially equal to the angle θ. Thus, the airflow generated from the fan 18 flows through the slots 38 smoothly and with low resistance. This improves heat dissipation efficiency of the thermal module 10.

It is understood that the invention may be embodied in other forms without departing from the spirit thereof. Thus, the present example and embodiment is to be considered in all respects as illustrative and not restrictive, and the invention is not to be limited to the details given herein.

1. A thermal module comprising:
a housing comprising a contact portion, a receiving portion and a fixing portion;
a fan fixed to the fixing portion of the housing, the fan generating airflow toward the receiving portion;
a heat sink received in the receiving portion of the housing, the heat sink having a plurality of fins defining a plurality of slots therebetween, the slots being substantially aligned with a direction of the airflow generated from the fan; and
a heat pipe attached to the contact portion of the housing and the heat sink.

2. The thermal module as claimed in claim 1, wherein the heat sink has an end surface, a first angle is defined between the end surface and any of the fins, a second angle is defined between the end surface and the direction of the airflow, and the first angle is substantially equal to the second angle.

3. The thermal module as claimed in claim 1, wherein the contact portion of the housing defines a first recess, the heat sink defines a second recess above the fins, and the heat pipe is received in the first and second recesses.

4. The thermal module as claimed in claim 1, wherein the receiving portion of the housing defines an opening for receiving the airflow generated from the fan.

5. The thermal module as claimed in claim 1, wherein the receiving portion of the housing extends from the contact portion, and the fixing portion extends from the receiving portion.

6. The thermal module as claimed in claim 1, wherein the fins are parallel to each other.

7. A thermal module comprising:
a housing comprising a receiving portion, and a fixing portion extending from the receiving portion;
a fan fixed to the fixing portion of the housing, the fan generating airflow toward the receiving portion; and
a heat sink received in the receiving portion of the housing, the heat sink having a plurality of fins defining a plurality of slots therebetween, and further having an end surface, a first angle being defined between the end surface and any of the fins, a second angle being defined between the end surface and a direction of the airflow generated from the fan, the first angle being substantially equal to the second angle.

8. The thermal module as claimed in claim 7, wherein the housing further comprises a contact portion extending from the receiving portion, and the thermal module further comprises a heat pipe attached to the contact portion and the heat sink.

9. The thermal module as claimed in claim 8, wherein the contact portion defines a first recess, the heat sink defines a second recess above the fins, and the heat pipe is received in the first and second recesses.

10. The thermal module as claimed in claim 7, wherein the fins are parallel to each other.

11. A thermal module comprising:
a housing comprising a contact portion, a receiving portion and a fixing portion;
a fan fixed to the fixing portion of the housing, the fan generating airflow toward the receiving portion;
a heat sink received in the receiving portion of the housing, the heat sink having a plurality of fins defining a plurality of slots therebetween, at least one slot being substantially aligned with a direction of the airflow generated from the fan; and
a heat pipe attached to the contact portion of the housing and the heat sink.

12. The thermal module as claimed in claim 11, wherein the heat sink has an end surface, a first angle is defined between the end surface and the at least one fin, a second angle is defined between the end surface and the direction of the airflow, and the first angle is substantially equal to the second angle.

13. The thermal module as claimed in claim 11, wherein the contact portion of the housing defines a first recess, the heat sink defines a second recess above the fins, and the heat pipe is received in the first and second recesses.

14. The thermal module as claimed in claim 11, wherein the receiving portion of the housing defines an opening for receiving the airflow generated from the fan.

15. The thermal module as claimed in claim 11, wherein the receiving portion of the housing extends from the contact portion, and the fixing portion extends from the receiving portion.

16. The thermal module as claimed in claim 11, wherein the fins are parallel to each other.

17. The thermal module as claimed in claim 11, wherein said fins and said fan are side by side located with each other.
